(19) United States
(12) Patent Application Publication
(10) Pub. No.: US 2025/0341771 A1
(43) Pub. Date: Nov. 6, 2025

(54) METHOD FOR MANUFACTURING THIN FILM-EQUIPPED SUBSTRATE, THIN FILM-EQUIPPED SUBSTRATE, METHOD FOR MANUFACTURING MULTILAYER REFLECTIVE FILM-EQUIPPED SUBSTRATE, MULTILAYER REFLECTIVE FILM-EQUIPPED SUBSTRATE, REFLECTIVE MASK BLANK, METHOD FOR MANUFACTURING REFLECTIVE MASK, AND METHOD FOR MANUFACTURING SEMICONDUCTOR DEVICE

(71) Applicant: HOYA CORPORATION, Tokyo (JP)

(72) Inventors: Kentaro IWAMOTO, Tokyo (JP); Tsutomu SHOKI, Tokyo (JP); Kenta TSUKAGOSHI, Tokyo (JP); Masahiro HASHIMOTO, Tokyo (JP)

(73) Assignee: HOYA CORPORATION, Tokyo (JP)

(21) Appl. No.: 18/864,722

(22) PCT Filed: Jun. 23, 2023
(86) PCT No.: PCT/JP2023/023270

§ 371 Date: Nov. 11, 2024

(30) Foreign Application Priority Data
Jun. 29, 2022 (JP) 2022-105149

(51) Int. Cl. G03F 1/38; G03F 1/24

(52) U.S. Cl. CPC G03F 1/38; G03F 1/24

(57) ABSTRACT

Provided is a method for manufacturing a thin film-equipped substrate, the method making it possible to detect an identification mark-symbol when performing a defect inspection on the thin film-equipped substrate, and easily performing an individual identification of the thin film-equipped substrate and an association a correlation between defect information of a thin film and the identification marksymbol. When a defect inspection is performed on a thin film-equipped substrate that includes a substrate and a thin film formed on the substrate, and has an identification mark-symbol unique to the thin film-equipped substrate in a region having no influence on pattern transfer of a surface on the side where the thin film is formed of on the thin film-equipped substrate, defect information of the thin film and the identification mark-symbol are detected. Consequently, an individual identification of the thin film-equipped substrate and an association a correlation between the detected defect information of the thin film and the identification mark-symbol are performed.

### CROSS-REFERENCE TO RELATED APPLICATIONS

This application is the National Stage of International Application No. PCT/JP2023/023270, filed Jun. 23, 2023, which claims priority to Japanese Patent Application No. 2022-105149, filed Jun. 29, 2022, and the contents of which is incorporated by reference.

### TECHNICAL FIELD

The present disclosure relates to a method for manufacturing a thin film coated substrate used in manufacturing a semiconductor device, a thin film coated substrate, a method for manufacturing a multilayer reflective film coated substrate, a multilayer reflective film coated substrate, a reflective mask blank, a method for manufacturing a reflective mask, and a method for manufacturing a semiconductor device.

### BACKGROUND ART

Generally, in a manufacturing process of a semiconductor device, a fine pattern is formed using photolithography. In forming the fine pattern, a number of transfer masks called photomasks are commonly used. The transfer mask generally comprises a transparent glass substrate and a fine pattern made of a metal thin film that is formed on the transparent glass substrate. In manufacture of the transfer mask, photolithography is used also.

In the manufacture of the transfer mask by photolithography, a mask blank is used which comprises a transparent substrate, such as a glass substrate, and a thin film (for example, a light shielding film) for forming a transfer pattern (mask pattern) on the transparent substrate. The manufacture of the transfer mask using the mask blank is carried out via a drawing step of drawing a desired pattern on a resist film formed on the mask blank, a developing step of developing the resist film after the drawing step to form a desired resist pattern, an etching step of etching the thin film using the resist pattern as a mask, and a step of peeling and removing the remaining resist pattern. In the aforementioned developing step, after the desired pattern is drawn on the resist film formed on the mask blank, a developer is supplied to dissolve a part of the resist film, which is soluble to the developer, to form the resist pattern. In the etching step, dry etching or wet etching is performed with the resist pattern used as the mask to remove an exposed part of the thin film where no resist pattern is formed, thereby forming a desired mask pattern on the transparent substrate. Thus, the transfer mask is completed.

As types of the transfer mask, a phase shift mask is known in addition to an existing binary mask having a light shielding film pattern of a chromium-based material formed on a transparent substrate.

Recently in the semiconductor industry, a fine pattern exceeding a transfer limit of traditional photolithography using ultraviolet light is required following an increase in degree of integration of a semiconductor device. As a technique enabling formation of such a fine pattern, there is EUV lithography which is an exposure technique using extreme ultra violet (Extreme Ultra Violet: hereinafter referred to as “EUV”) light. It is noted here that the EUV light refers to light in a wavelength band of a soft X-ray region or a vacuum ultraviolet region, specifically, light having a wavelength of about 0.2 to 100 nm. As a mask used in the EUV lithography, there is a reflective mask. The reflective mask comprises a substrate, a multilayer reflective film formed on the substrate to reflect the EUV light serving as exposure light, and a patterned absorber film formed on the multilayer reflective film to absorb the EUV light.

As described above, there is an increasing demand for miniaturization of patterns in a lithography process, but new problems arise also. One of the problems is a problem concerned in mask blank substrate management on receiving inspection by customers.

In the past, for example, Patent Literature 1 describes a glass substrate for a mask blank provided with a pit which is formed, by irradiation of laser light, on a mirror-like surface in a region, having no influence on transfer, on a surface of the glass substrate for the mask blank, and which is used as a marker for identifying or managing the aforementioned glass substrate and/or the mask blank with a mask pattern thin film formed on the aforementioned glass substrate to serve as a mask pattern.

### PRIOR ART LITERATURE(S)

### Patent Literature(s)

Patent Literature 1: JP 2006-309143 A

Patent Literature 2: JP 2015-043100 A

### SUMMARY OF THE DISCLOSURE

### Problems to be Solved by the Disclosure

However, when the aforementioned marker is formed by the laser light as described in Patent Literature 1, dust generation occurs to cause a defect. Therefore, practical application has been difficult. In particular, in a multilayer reflective film coated substrate or a reflective mask blank for which the EUV light is used, there are very strict requirements regarding the defect. This makes it difficult to apply the above-mentioned prior art technique. In the multilayer reflective film coated substrate or the reflective mask blank, individual identification has been performed by comparison with a defect map prior to fabrication of the reflective mask. However, when the number of defects is small or zero, the individual identification of the multilayer reflective film coated substrate or the reflective mask blank is difficult because the comparison with the defect map is impossible.

Patent Literature 2 proposes to perform drawing management using a mask substrate with an ID (identifier) which is optically readable by a reading device, coded, and formed on a side of a glass substrate. However, in Patent Literature 2, it was difficult to perform, by a simple process, individual identification management of the multilayer reflective film coated substrate or the reflective mask blank starting from a film formation stage of a multilayer reflective film.

In view of the above-mentioned problems in the prior art, the present disclosure has been made. It is a first aspect of the present disclosure to provide a method for manufacturing a thin film coated substrate, a thin film coated substrate, a method for manufacturing a multilayer reflective film coated substrate, a multilayer reflective film coated substrate, a reflective mask blank, and a method for manufacturing a reflective mask, wherein the thin film coated substrate, such as the multilayer reflective film coated substrate, the mask blank, or the like, is provided with a unique identification symbol (ID) and the identification symbol can be detected when defect inspection is performed on the thin film coated substrate, thereby facilitating individual identification of the thin film coated substrate and correlation between defect information of a thin film and the identification symbol.

It is a second aspect of the present disclosure to provide a method for manufacturing a semiconductor device using the reflective mask.

### Means for Solving the Problem

As a result of continuing intensive studies to solve the problems in the prior art, the present inventors have completed the following disclosure.

### (Configuration 1)

A method for manufacturing a thin film coated substrate comprising a substrate and a thin film formed on the substrate; the method comprising:
providing the thin film coated substrate which includes an identification symbol, unique to the thin film coated substrate, on a surface of the thin film coated substrate on the side where the thin film is formed and in a region having no influence on pattern transfer;
detecting defect information of the thin film and the identification symbol when defect inspection is performed on the thin film coated substrate; and
correlating the identification symbol with the defect information of the thin film.

### (Configuration 2)

The method for manufacturing a thin film coated substrate according to configuration 1, wherein the identification symbol has a size of 10 μm to 500 μm.

### (Configuration 3)

The method for manufacturing a thin film coated substrate according to configuration 1 or 2, wherein:
the substrate is a 6-inch square substrate; and
the region having no influence on pattern transfer is a belt-like region between a pattern forming region having a size of 132 mm×132 mm and a region having a size of 148 mm×148 mm.

### (Configuration 4)

The method for manufacturing a thin film coated substrate according to any one of configurations 1 to 3, wherein a reference mark is provided in the region having no influence on pattern transfer.

### (Configuration 5)

The method for manufacturing a thin film coated substrate according to any one of configurations 1 to 4, wherein the thin film comprises a stacked film including two or more layers, the method including performing two or more defect inspections after formation of the respective layers of the stacked film, and detecting the identification symbol when each defect inspection is performed.

### (Configuration 6)

A thin film coated substrate comprising
a substrate; and
a thin film formed on the substrate, wherein
an identification symbol unique to the thin film coated substrate is provided on a surface of the thin film coated substrate on the side where the thin film is formed and in a region having no influence on pattern transfer, the identification symbol being detectable when defect inspection is performed on the thin film.

### (Configuration 7)

The thin film coated substrate according to configuration 6, wherein the identification symbol has a size of 10 μm to 500 μm.

### (Configuration 8)

The thin film coated substrate according configurations 6 or 7, wherein: the substrate is a 6-inch square square-shaped substrate: and
the region having no influence on pattern transfer is a belt-like region between a pattern forming region having a size of 132 mm×132 mm and a region having a size of 148 mm×148 mm.

### (Configuration 9)

The thin film coated substrate according to any one of configurations 6 to 8, wherein a reference mark is provided in the region having no influence on pattern transfer.

The thin film may be a multilayer reflective film which reflects EUV light, and the thin film coated substrate may be a multilayer reflective film coated substrate.

A reflective mask blank may comprise the above-mentioned multilayer reflective film coated substrate, and an absorber film formed on the multilayer reflective film coated substrate to absorb EUV light.

The method for manufacturing a reflective mask may include patterning the absorber film of the above-mentioned reflective mask blank to form an absorber film pattern.

In a method for manufacturing a semiconductor device, the method may include a step of transferring by exposure a transfer pattern to a resist film on a semiconductor substrate by using a reflective mask manufactured by the above-mentioned method for manufacturing a reflective mask.

### Effect of the Disclosure

According to the present disclosure, the thin film coated substrate, such as the multilayer reflective film coated substrate, the mask blank, or the like, is provided with the unique identification symbol (ID) and the identification symbol can be detected when defect inspection is performed on the thin film coated substrate. Thus, individual identification of the thin film coated substrate and correlation between the defect information of the thin film and the identification symbol can be facilitated so as to perform appropriate one-by-one management for the thin film coated substrate, the multilayer reflective film coated substrate, the reflective mask blank, and so on. In addition, it is possible to provide a method for manufacturing a semiconductor device using the reflective mask.

### BRIEF DESCRIPTION OF THE DRAWINGS

FIG. 1 is a plan view showing a multilayer reflective film coated substrate according to one embodiment of the present disclosure;

FIG. 2 is a schematic cross-sectional view of the multilayer reflective film coated substrate shown in FIG. 1;

FIG. 3 shows an example of a shape of an identification symbol;

FIG. 4 shows another example of the shape of the identification symbol;

FIGS. 5A to 5D show examples of a shape of a first reference mark;

FIGS. 6A to 6D show, in schematic cross-sectional views, a manufacturing process of a reflective mask blank and a reflective mask according to one embodiment of the present disclosure;

FIGS. 7A to 7D show examples of a shape of a second reference mark; and

FIG. 8 is a plan view showing the reflective mask blank according to the one embodiment of the present disclosure.

### MODE FOR EMBODYING THE DISCLOSURE

Hereinafter, an embodiment of the present disclosure will be described in detail.

As described above, a method for manufacturing a thin film coated substrate according to the present disclosure is a method for manufacturing the thin film coated substrate including a substrate and a thin film formed on the substrate, wherein the method includes: providing an identification symbol, unique to the thin film coated substrate, on a surface of the thin film coated substrate on the side where the thin film is formed and in a region having no influence on pattern transfer; detecting defect information of the thin film and the identification symbol when defect inspection is performed on the thin film coated substrate; and correlating the identification symbol with the defect information of the thin film.

As described above, a thin film coated substrate according to the present disclosure is a thin film coated substrate that includes a substrate and a thin film formed on the substrate, wherein: an identification symbol or code unique to the thin film coated substrate is provided on a surface of the thin film coated substrate on the side where the thin film is formed and in a region having no influence on pattern transfer, the identification symbol being detectable when defect inspection is performed on the thin film.

When the thin film coated substrate in the present disclosure is, for example, a reflective mask blank for EUV exposure, the thin film referred to herein may be an underlayer, a multilayer reflective film, a protective film, an absorber film, a hard mask film (etching mask film), and/or a backside conductive film. When the thin film coated substrate in the present disclosure is, for example, a photomask blank for ultraviolet exposure, the thin film may be a light shielding film, a phase shift film, and/or a hard mask film (etching mask film).

In the present disclosure, it is important that the identification symbol (ID) unique to the thin film coated substrate is provided on the surface of the thin film coated substrate on the side where the thin film is formed, and in the region having no influence on pattern transfer.

The identification symbol (ID) has a shape capable of providing information for identifying each individual substrate. Specifically, various symbols including a two-dimensional code such as a QR code (registered trademark), a bar code, alphanumeric characters, and a dot mark array, and so on may be applied as the identification symbol (ID).

Furthermore, the identification symbol (ID) can be detected when defect inspection is performed on the thin film coated substrate. That is, the identification symbol is detectable by inspection light of a defect inspection device to be used. Therefore, the identification symbol may preferably have a size of approximately 10 μm to 500 μm depending on a wavelength of an inspection light source of the defect inspection device to be used. In addition, the description “detect the defect information and the identification symbol when the defect inspection is performed” or the description “detectable when the defect inspection is performed” means that the identification symbol (ID) is also detected during a series of operations of detecting the defect information by scanning or imaging the thin film by one defect inspection device. That is, by providing the identification symbol (ID) in a scanning and imaging region (defect inspection region) for acquiring the defect information, the defect information and the identification symbol (ID) can be detected simultaneously. The identification symbol (ID) may be provided in a region different from the scanning and imaging region for acquiring the defect information. In this case, it is possible by the defect inspection device to acquire the defect information following detection of the identification symbol (ID) or to detect the identification symbol (ID) following acquisition of the defect information.

The defect information includes information related to a position, a size, and/or a type of a defect. In addition to the defect information, thin film information and/or substrate information may be correlated with the identification symbol. The thin film information may be information including at least one of physical properties, chemical properties, electrical properties, optical properties, a surface form of a thin film surface, a material, and a film-forming condition of the thin film. The substrate information may be information including at least one of physical properties, chemical properties, optical properties, a surface form of a substrate surface, a shape, a material, and a defect of a glass substrate. The surface form of the thin film surface or the substrate surface may be surface roughness, waviness, flatness, degree of parallelization, convex shape, concave shape, or the like.

When the identification symbol (ID) is provided on the surface of the thin film coated substrate on the side where the thin film is formed, the region having no influence on pattern transfer may be a belt-like region between a pattern formation region of 132 mm×132 mm and a region of 148 mm×148 mm in a case where the substrate has a size of about 152.0 mm×about 152.0 mm (6 inch square). Alternatively, the region having no influence on pattern transfer may be a belt-like region between a pattern formation region of 132 mm×132 mm and a region of 142 mm×142 mm.

The region having no influence on pattern transfer may have a reference mark (also referred to as an alignment mark (AM)) which may be used as a reference for defect coordinates when the defect on the thin film is inspected by the defect inspection device, or a reference mark (also referred to as a fiducial mark (FM)) which may be used as a reference for defect coordinates during pattern drawing by an electron beam drawing device. Details of the alignment mark (AM) and the fiducial mark (FM) will be described later.

When the thin film of the thin film coated substrate comprises a stacked film composed of two or more layers, for example, when at least the multilayer reflective film and the absorber film are provided on the substrate as in the reflective mask blank, it is possible to perform defect inspection twice or more among timings after the respective layers of the stacked film are formed and to detect the identification symbol when each defect inspection is performed. Specifically, after the multilayer reflective film is formed, the defect inspection is performed to detect the defect information and the identification symbol. Thereafter, the absorber film is formed on the multilayer reflective film and the defect inspection of the absorber film is performed to detect the defect information and the identification symbol.

According to the present disclosure, the thin film coated substrate, such as the multilayer reflective film coated substrate, the mask blank, or the like, is provided with the unique identification symbol (ID) and the identification symbol can be detected when defect inspection is performed on the thin film coated substrate. Thus, individual identification of the thin film coated substrate and correlation between the defect information of the thin film and the identification symbol can be facilitated so as to perform appropriate one-by-one management for the thin film coated substrate, the multilayer reflective film coated substrate, the reflective mask blank, and so on.

The present disclosure also provides a method for manufacturing a thin film coated substrate including a mask blank substrate and a thin film formed on the mask blank substrate. The method is characterized by providing an identification symbol unique to the thin film coated substrate on a surface of the thin film coated substrate on the side where the thin film is formed and in a region having no influence on pattern transfer, detecting the identification symbol at a wavelength same as that of inspection light in defect inspection of the thin film, and correlating the identification symbol with defect information of the substrate which is obtained by defect inspection of the mask blank substrate.

Next, description will be made as regards a method for manufacturing a multilayer reflective film coated substrate and a multilayer reflective film coated substrate according to one embodiment of a method for manufacturing a thin film coated substrate and a thin film coated substrate according to the present disclosure.

### Method for Manufacturing Multilayer Reflective Film Coated Substrate, Multilayer Reflective Film Coated Substrate

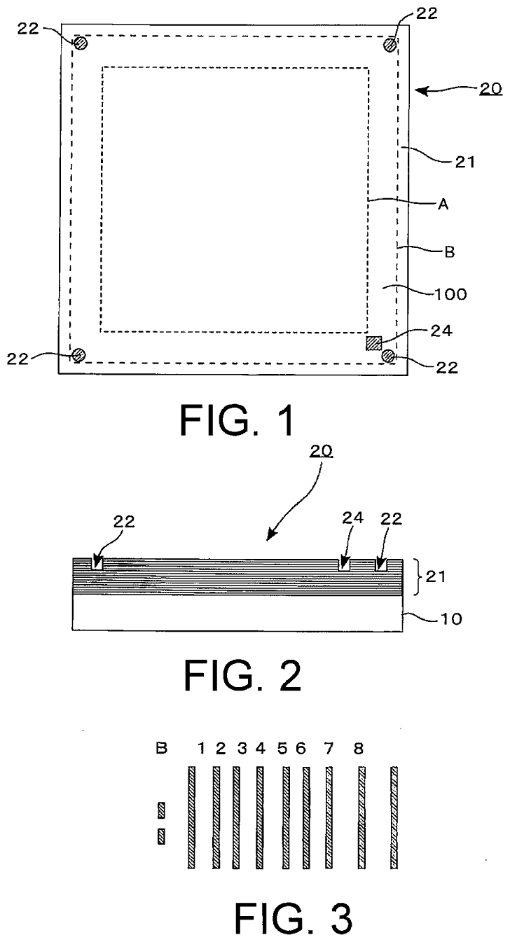

FIG. 1 is a plan view showing a multilayer reflective film coated substrate according to one embodiment of the present disclosure, and FIG. 2 is a schematic cross-sectional view of the multilayer reflective film coated substrate shown in FIG. 1.

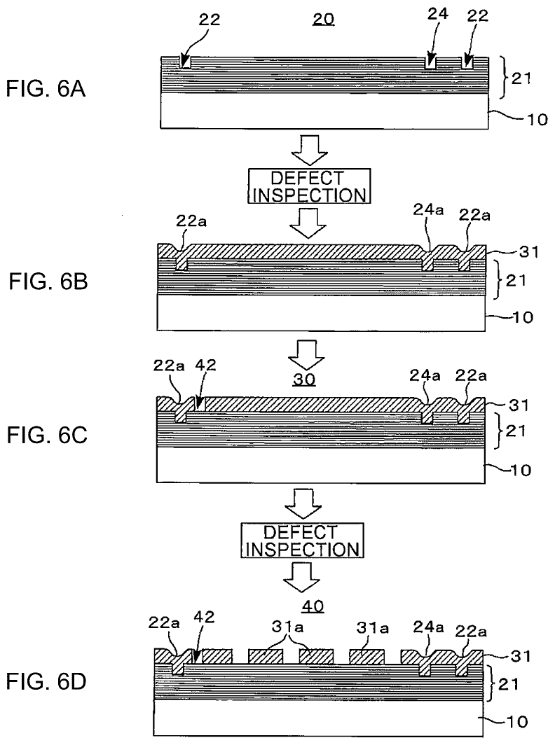

As illustrated in FIGS. 1 and 2, the multilayer reflective film coated substrate 20 according to one embodiment of the present disclosure comprises a glass substrate 10 (hereinafter referred to as a substrate) and at least a multilayer reflective film 21 formed on the substrate 10 to reflect EUV light as exposure light. On a main surface of the multilayer reflective film coated substrate 20, an identification symbol (ID) 24 unique to the multilayer reflective film coated substrate 20 is provided at one of positions near four corners in a belt-like region 100 between a pattern forming region (in a region depicted by a broken line A in FIG. 1) and a scanning and imaging region (defect inspection region) (in a region depicted by a broken line B in FIG. 1). The belt-like region 100 is on the main surface of the multilayer reflective film coated substrate 20 on the side where the multilayer reflective film 21 is formed, and is a region having no influence on pattern transfer. The pattern forming region is a region where a transfer pattern is to be formed in an absorber film 31 (FIGS. 6B to 6D) which will later be described and is, for example, a region of 132 mm×132 mm in a 6-inch square substrate. The scanning and imaging region (defect inspection region) is, for example, a region of 148 mm×148 mm in the 6-inch square substrate.

Also, near the four corners in the belt-like region 100, first reference marks 22 (alignment marks (AM) mentioned above) are formed to serve as a reference for the defect information of the multilayer reflective film.

The multilayer reflective film coated substrate 20 according to the present embodiment is manufactured by forming, on the substrate 10, the multilayer reflective film 21 reflecting the exposure light, for example, the EUV light (see FIG. 2).

As a substrate for the EUV exposure, the substrate 10 is preferably used. In particular, in order to prevent pattern deformation due to heat during the exposure, the substrate having a low thermal expansion coefficient within a range of 0±1.0×10⁻⁷/° C. is preferably used, more preferably within a range of 0±0.3×10⁻⁷/° C. As a material having the low thermal expansion coefficient in the above-mentioned range, for example, SiO₂-TiO₂-based glass, multi-component glass ceramics, or the like may be used.

A main surface of the substrate 10 on the side where the transfer pattern is to be formed is surface-treated to have high flatness from the viewpoint of improving at least pattern transfer accuracy and positional accuracy. In the case of the EUV exposure, the flatness is preferably 0.1 μm or less, particularly preferably 0.05 μm or less, in a region of 142 mm×142 mm on the main surface of the substrate 10 on the side where the transfer pattern is to be formed. The other main surface opposite from the side where the transfer pattern is to be formed is a surface to be electrostatically chucked when the substrate is set in an exposure apparatus, and has flatness of 0.1 μm or less, preferably 0.05 μm or less, in a region of 142 mm×142 mm.

As described above, the material, such as SiO₂-TiO₂-based glass, having the low thermal expansion coefficient is preferably used as the substrate 10. However, such a glass material is difficult to achieve high smoothness of, for example, 0.1 nm or less in root mean square roughness (Rq) as surface roughness by precision polishing. Therefore, an underlayer may be formed on the surface of the substrate 10 for the purpose of reducing the surface roughness of the substrate 10 or reducing defects on the surface of the substrate 10. As a material of the underlayer, which need not be transparent to the exposure light, a material exhibiting high smoothness and excellent defect quality when a surface of the underlayer is precision-polished is preferably selected. For example, Si or a silicon compound (such as SiO₂, SiON, etc.) containing Si exhibiting high smoothness and excellent defect quality when precision-polished and, therefore, is preferably used as the material of the underlayer. As the material of the underlayer, Si is particularly preferable.

Preferably, the surface of the underlayer is a surface precision-polished so as to have smoothness required as a reflective mask blank substrate. Desirably, the surface of the underlayer is precision-polished to have root-mean square roughness (Rq) of 0.15 nm or less, particularly preferably 0.1 nm or less. In addition, taking the influence on a surface of the multilayer reflective film 21 to be formed on the underlayer, the surface of the underlayer is desirably precision-polished so that, in relation to a maximum height (Rmax), Rmax/Rq is 2 to 10, particularly preferably 2 to 8. The underlayer preferably has a film thickness in the range of, for example, 10 nm to 300 nm.

The multilayer reflective film 21 is a multilayer film in which low refractive index layers and high refractive index layers are alternately stacked. Generally used is a multilayer film in which thin films of a heavy element or a compound thereof and thin films of a light element or a compound thereof are alternately stacked by about 40 to 60 periods.

For example, as the multilayer reflective film for the EUV light having a wavelength of 13 to 14 nm, preferably used is a Mo/Si periodically stacked film in which Mo films and Si films are alternately stacked by about 40 periods. In addition, as the multilayer reflective film used in the EUV region, there are a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, a Si/Ru/Mo/Ru periodic multilayer film, and so on. The material may appropriately be selected depending on an exposure wavelength.

Typically, for the purpose of protecting the multilayer reflective film during patterning of the absorber film or pattern correction, a protective film (may also be referred to as a capping layer or a buffer film) is preferably formed on the multilayer reflective film 21. The protective film is formed of, for example, a material containing ruthenium as a main component. The material containing ruthenium as the main component includes Ru elemental metal, an Ru alloy containing Ru and at least one metal selected from titanium (Ti), niobium (Nb), rhodium (Rh), molybdenum (Mo), zirconium (Zr), yttrium (Y), boron (B), lanthanum (La), cobalt (Co), and rhenium (Re), and a material containing nitrogen in addition to the Ru elemental metal or the Ru alloy. The protective film preferably has a film thickness in a range of about 1 nm to 5 nm.

A film forming method of the underlayer, the multilayer reflective film 21, and the protective film is not particularly limited. Typically, ion beam sputtering, magnetron sputtering, and so on are suitable.

FIG. 1 and FIG. 2 show the one embodiment of the multilayer reflective film coated substrate 20 in which the multilayer reflective film 21 is formed on the substrate 10 as described above. In the present disclosure, however, the multilayer reflective film coated substrate includes an embodiment in which the multilayer reflective film 21 and the protective film are formed on the substrate 10 in this order and another embodiment in which the underlayer, the multilayer reflective film 21, and the protective film are formed on the substrate 10 in this order.

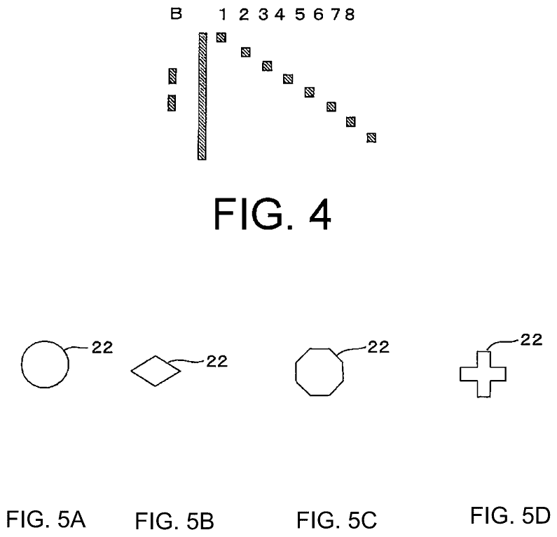

As described above, the identification symbol 24 has a shape capable of providing information for identifying each individual substrate. As the identification symbol 24, for example, various symbols including a two-dimensional code such as a QR code (registered trademark), a bar code, alphanumeric characters, a line array with different line-to-line widths as shown in FIG. 3, or a dot mark array as shown in FIG. 4 may be applied. For example, in FIG. 3, alphabets can be represented by short lines and numerals can be defined by widths between long lines. In FIG. 4, alphabets can be represented by short lines and numerals can be defined by the dot mark array in longitudinal and transverse directions with respect to a long line. The identification symbol 24 may have any shape adapted to provide information for identifying each individual substrate and is not limited to the above-mentioned examples.

The identification symbol 24 is detectable by inspection light of a defect inspection device to be used. For example, as a defect inspection device for a reflective mask, a reflective mask blank which is an original plate of the reflective mask, a multilayer reflective film coated substrate, and a substrate, there are widely used an EUV exposure mask substrate/blank defect inspection device “MAGICS M7360”, manufactured by Lasertec, having an inspection light source of a wavelength of 266 nm, an EUV exposure mask substrate/blank defect inspection device “MAGICS M8650”, manufactured by Lasertec, having an inspection light source of a wavelength of 355 nm, an EUV exposure mask substrate/blank defect inspection device “MAGICS M9650”, manufactured by Lasertec, having an inspection light source of a wavelength of 213 nm, a mask/blank defect inspection device “Teron 600 Series, for example, Teron 610”, manufactured by KLA-Tencor, having an inspection light source of a wavelength of 193 nm, and so on. As a defect inspection device for a multilayer reflective film coated substrate, an ABI (Actinic Blank Inspection) device is preferable, which uses an inspection light source of a wavelength of 13.5 nm equal to that of an exposure light source. It is also possible to use an atomic force microscope (AFM), a scanning electron microscope (SEM), or an EUV light microscope, which is capable of obtaining asperity information of a surface of a defect. Furthermore, it is possible to use a coordinate measuring instrument “LMS-IPRO4”, manufactured by KLA-Tencor, which performs coordinate measurement using a laser of a wavelength of 365 nm, or a coordinate measuring instrument “PROVE”, manufactured by Carl Zeiss. which performs coordinate measurement using a laser of a wavelength of 193 nm.

Therefore, it is advantageous that the identification symbol 24 has a size falling within a rectangle of 10 μm to 500 μm, preferably 10 μm to 200 μm, more preferably 80 μm to 120 μm in length and 10 μm to 500 μm, preferably 10 μm to 200 μm, more preferably 80 μm to 120 μm in width, depending on the wavelength of the inspection light source of the defect inspection device to be used.

In the present embodiment, the identification symbol 24 forms a concave shape (cross-sectional shape) having a desired depth in the multilayer reflective film 21, for example, by laser light, a focused ion beam, photolithography, indentation (punch) by a microindenter, a machining mark obtained by scanning with a diamond needle, die pressing by imprinting, or the like. It is preferable to form the identification symbol 24 using a semiconductor laser. When the cross-sectional shape of the identification symbol 24 is the concave shape, the cross-sectional shape may preferably be widened from a bottom toward a surface of the concave shape from the viewpoint of improving detection accuracy by defect inspection light. The cross-sectional shape of the identification symbol 24 is not limited to the concave shape and may be a convex shape or any cross-sectional shape which can be accurately detected by the defect inspection device.

In the present embodiment, the identification symbol 24 is formed on the surface of the multilayer reflective film 21. However, when the protective film is formed on the multilayer reflective film 21 as mentioned above, the identification symbol 24 may be formed on a surface of the protective film.

In the present embodiment, the identification symbol 24 is provided at one of the positions near the corners in the belt-like region 100 having no influence on transfer, but may be provided at two to four positions. Also, the identification symbol need not be formed near the corners.

When the first reference marks 22 as a reference for the defect information of the multilayer reflective film 21 are provided in the same belt-like region 100 as in the present embodiment, that is, when the identification symbol 24 and the first reference marks 22 have a positional relationship of being included in the same region, the identification symbol 24 is preferably formed at a position close to at least one first reference mark 22 and causing no confusion with the first reference mark 22. For example, the identification symbol 24 and the first reference mark 22 are preferably formed in a region bounded by 3×3 mm.

In the present embodiment, the identification symbol 24 is formed on the surface of the multilayer reflective film 21, but may be formed on the surface or a side of the substrate 10. When the underlayer is provided between the substrate 10 and the multilayer reflective film 21, the identification symbol 24 may be formed on the surface of the underlayer. When the identification symbol 24 is formed on the surface of the substrate 10 or the underlayer, the shape of the identification symbol 24 is transferred to the multilayer reflective film 21.

Next, the first reference marks 22 will be described.

FIGS. 5A to 5D show shapes of the first reference marks 22.

In the foregoing embodiment, the first reference marks 22 to serve as a reference for the defect information of the multilayer reflective film 21 are formed at four positions near the corners in the belt-like region 100 having no influence on transfer.

The first reference marks 22 serve as a reference for a defect position in the defect information. Preferably, the first reference marks 22 each have a point-symmetric shape. Furthermore, in a case where the ABI device or the like using, as defect inspection light, short-wavelength light having a wavelength shorter than, for example, 100 nm is used for defect inspection, it is preferable that the first reference marks 22 each have a portion having a width of 30 nm or more and 1000 nm or less with respect to a scanning direction of the defect inspection light.

FIGS. 5A to 5D show several shapes of the first reference marks 22. A typical example is a circular reference mark as shown in FIG. 5A. The first reference mark may have, for example, a rhombic shape as shown in FIG. 5B, an octagonal shape as shown in FIG. 5C, and a cross shape as shown in FIG. 5D. Although not shown in the figure, the first reference marks 22 may have a square shape or a square shape with rounded corners.

The first reference marks 22 having the point-symmetric shape make it possible to reduce a deviation of a reference point for the defect position, for example, determined by scanning with the defect inspection light, and to reduce a variation in a defect detection position inspected with reference to the first reference marks 22.

Like the identification symbol 24, the first reference marks 22 each forms a concave shape (cross-sectional shape) having a desired depth in the multilayer reflective film 21, for example, by laser light of a semiconductor laser or the like, a focused ion beam, photolithography, indentation (punch) by a microindenter, a machining mark obtained by scanning with a diamond needle, die pressing by imprinting, or the like. When the cross-sectional shape of the first reference marks 22 is the concave shape, the cross-sectional shape is preferably widened from a bottom toward a surface of the concave shape from the viewpoint of improving detection accuracy by defect inspection light. The cross-sectional shape of the first reference marks 22 is not limited to the concave shape and may have a convex shape or any cross-sectional shape which can be accurately detected by the defect inspection device.

As described above, according to the present embodiment, the multilayer reflective film coated substrate 20 is provided with the unique identification symbol 24 which is detectable by the defect inspection device. This makes it possible to detect the identification symbol when the defect inspection is performed on the multilayer reflective film coated substrate 20, to easily perform individual identification of the multilayer reflective film coated substrate 20 and correlation between the defect information of the multilayer reflective film and the identification symbol, and to perform appropriate one-by-one management for the multilayer reflective film coated substrate 20. In addition to the defect information of the multilayer reflective film, for example, the substrate information such as the flatness of the substrate described above can easily be correlated with the identification symbol. Furthermore, in addition to the defect information of the multilayer reflective film, the above-mentioned thin film information can easily be correlated with the identification symbol. The defect information, the substrate information, or the thin film information which are correlated with the identification symbol may be provided to a customer.

### Reflective Mask Blank and Method for Manufacturing Reflective Mask

Next, description will be made as regards a reflective mask blank according to one embodiment of the present disclosure and a method for manufacturing a reflective mask using the reflective mask blank.

FIGS. 6A to 6D show, in schematic cross-sectional views, a manufacturing process of a reflective mask blank and a reflective mask according to one embodiment of the present disclosure, and FIG. 8 is a plan view showing the reflective mask blank according to the one embodiment of the present disclosure.

FIG. 6A shows the multilayer reflective film coated substrate 20 described above. As described above, the multilayer reflective film coated substrate 20 has the identification symbol 24 and the first reference marks 22 on the surface of the multilayer reflective film 21 in the region having no influence on transfer. The configuration of the multilayer reflective film coated substrate 20, the identification symbol 24, and the first reference marks 22 have already been described in detail and, therefore, repetitive description will be omitted herein.

Next, defect inspection is performed on the multilayer reflective film coated substrate 20 having the identification symbol 24 and the first reference marks 22. Specifically, the multilayer reflective film coated substrate 20, including the first reference marks 22, is subjected to the defect inspection by the defect inspection device to acquire the defect and the position information detected by the defect inspection, thereby obtaining the defect information including the first reference marks 22. In this case, the defect inspection is performed at least over an entire surface of the pattern forming region. Thus, the defect information (1st defect map) with respect to the first reference marks 22 is prepared.

As described above, the identification symbol 24 can be detected during a series of operations of the defect inspection on the multilayer reflective film coated substrate 20. The identification symbol 24 is unique to the multilayer reflective film coated substrate 20. By performing the defect inspection on the multilayer reflective film coated substrate 20 to simultaneously detect the defect information of the multilayer reflective film and the identification symbol 24, it is possible to perform the individual identification of the multilayer reflective film coated substrate 20 and the correlation between the defect information (defect map) of the multilayer reflective film and the identification symbol 24.

In addition, multiple inspections may be performed on the multilayer reflective film coated substrate 20 using defect inspection devices different in wavelength. In this case, in each defect inspection, the identification symbol 24 can be detected simultaneously with the defect inspection. By performing the multiple inspections on the multilayer reflective film coated substrate 20 to simultaneously detect each defect information and the identification symbol 24 of the multilayer reflective film, it is possible to perform defect management with higher accuracy.

As regards the defect inspection on the surface of the multilayer reflective film coated substrate 20, partial inspection in a shortened inspection time may be performed instead of entire surface inspection.

Next, the absorber film 31 which absorbs EUV light is formed on the entire surface of the multilayer reflective film 21 (or the protective film if the protective film is provided on the surface of the multilayer reflective film) in the multilayer reflective film coated substrate 20 to manufacture the reflective mask blank (see FIG. 6B).

Although not illustrated in the figure, a backside conductive film may be formed on the substrate 10 on the side opposite from the side where the multilayer reflective film is formed. In a case where the backside conductive film is formed, the identification symbol 24 may be formed on the surface of the substrate 10 where the backside conductive film is to be formed or on the backside conductive film. When the identification symbol 24 is formed on the surface of the substrate 10, the shape of the identification symbol 24 is transferred to the backside conductive film. This is suitable particularly when defect inspection is performed on the backside conductive film also.

The absorber film 31 has a function of absorbing exposure light, for example, EUV light. It is sufficient that, in the reflective mask 40 manufactured using the reflective mask blank (see FIG. 6D), a desired reflectance difference is obtained between reflected light reflected by the multilayer reflective film 21 (or the protective film when the protective film is provided on the surface of the multilayer reflective film) and reflected light reflected by an absorber film pattern 31a. For example, a reflectance of the absorber film 31 with respect to the EUV light is selected in a range of 0.1% or more and 40% or less. In addition to the reflectance difference, a desired phase difference may be provided between the reflected light reflected by the multilayer reflective film 21 (or the protective film when the protective film is provided on the surface of the multilayer reflective film) and the reflected light reflected by the absorber film pattern 31a. In a case where the desired phase difference is provided between the reflected light reflected by the multilayer reflective film 21 (or the protective film when the protective film is provided on the surface of the multilayer reflective film) and the reflected light reflected by the absorber film pattern 31a, the absorber film 31 in the reflective mask blank may be referred to as a phase shift film. In a case of improving a contrast by providing the desired phase difference between the reflected light reflected by the multilayer reflective film 21 (or the protective film when the protective film is provided on the surface of the multilayer reflective film) and the reflected light reflected by the absorber film pattern 31a, the phase difference is preferably set within a range of 170 degrees to 260 degrees and the reflectance of the absorber film 31 is preferably set within a range of 3% or more and 40% or less.

The absorber film 31 may comprise a single layer or a stacked structure. In a case of the stacked structure, a stacked film of the same material or a stacked film of different materials may be used. The stacked film may be a film changed in material or composition stepwise and/or continuously in a film thickness direction.

A material of the absorber film 31 is not particularly limited as long as the material has a function of absorbing the EUV light, is processable by etching or the like (preferably, etchable by dry etching with a chlorine (Cl)-based gas and/or a fluorine (F)-based gas), and has a high etching selectivity with respect to the protective film. As a material having those functions, it is preferable to use at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals, or a compound thereof. The compound may contain oxygen (O), nitrogen (N), carbon (C) and/or boron (B) in addition to the metal or the alloy.

The absorber film 31 has a film thickness preferably in a range of about 30 nm to 100 nm, for example. Although a film forming method of the absorber film 31 is not particularly limited, magnetron sputtering, ion beam sputtering, and the like are generally suitable.

By forming the absorber film 31, the identification symbol 24 and the first reference marks 22 on the surface of the multilayer reflective film 21 are transferred to a surface of the absorber film 31 also (see FIG. 6B). In the present embodiment, each of the identification symbol 24 and the first reference marks 22 has a concave cross-sectional shape. Therefore, an identification symbol 24a and first reference marks 22a, which are transferred with a concave cross-section, are formed on the surface of the absorber film 31.

Next, second reference marks 42 are formed on the surface of the absorber film 31 (see FIG. 6C). In the present embodiment, the second reference marks 42 are formed near the first reference marks 22a transferred to the surface of the absorber film 31 (see FIG. 8). As described above, the second reference marks 42 are reference marks (also referred to as fiducial marks (FM)) which may be used as a reference for defect coordinates during pattern drawing by an electron beam drawing device.

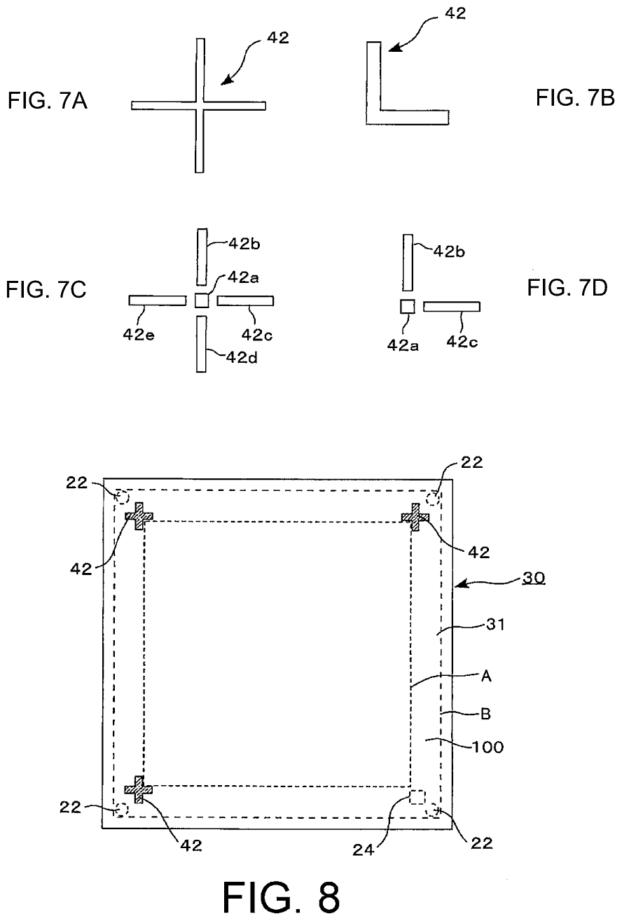

FIGS. 7A to 7D show several shapes of the second reference marks 42. A reference mark of a cross shape as shown in FIG. 7A is a typical example. Furthermore, may also be used a reference mark of an L shape as shown in FIG. 7B, a main mark 42a surrounded by four auxiliary marks 42b to 42e arranged at an angular interval of 90 degrees, or the main mark 42a surrounded by two auxiliary marks 42b and 42c arranged at an angular interval of 90 degrees as shown in FIG. 7D. It should be noted that the present disclosure is not limited to those embodiments of the second reference marks.

The cross shape in FIG. 7A, the L shape in FIG. 7B, and the auxiliary marks 42b to 42e (42b, 42c) arranged around the main mark 42a in FIG. 7C or 7D are preferably arranged along the scanning direction of the defect inspection light or the electron beam drawing device, and advantageously include a rectangular shape having a long side perpendicular to and a short side parallel to the scanning direction of the defect inspection light or the electron beam drawing device. The second reference marks each including the rectangular shape having the long side perpendicular to and the short side parallel to the scanning direction of the defect inspection light or the electron beam make it possible to reliably detect the second reference marks by scanning with the defect inspection device or the electron beam drawing device. Therefore, position of the second reference marks with respect to the first reference marks can easily be identified. In this case, the long side of each second reference mark desirably has a length detectable by a minimum number of times of scanning with the defect inspection device or the electron beam drawing device, for example, desirably has a length of 100 μm or more and 1500 μm or less.

In the present embodiment, the second reference marks 42 forms a concave shape (cross-sectional shape) having a desired depth in the absorber film 31, for example, by laser light of a semiconductor laser, photolithography, or a focused ion beam. However, the cross-sectional shape of the second reference marks 42 is not limited to the concave shape but may be a convex shape or any cross-sectional shape which can be accurately detectable by the defect inspection device or the electron beam drawing device.

In the present disclosure, the number of the first and the second reference marks is not particularly limited. The number of the first and the second reference marks must be at least three, and may be three or more.

In the present embodiment, the identification symbol 24 is formed at one of the positions near the corners in the belt-like region 100 which has no influence on transfer, but may be formed at two to four positions. The identification symbol 24 need not be formed near the corners. Furthermore, when the belt-like region 100 includes the identification symbol 24, the first reference marks 22, and the second reference marks 42 as in the present embodiment, that is, when the identification symbol 24, the first reference marks 22, and the second reference marks 42 have a positional relationship of being included in the same region, the second reference marks 42 are preferably formed at positions close to at least one of the first reference marks 22 and causing no confusion with the identification symbol 24.

Note that the first reference marks 22 can also serve as the second reference marks 42. In this case, the second reference marks 42 need not be formed on the absorber film 31.

In the above-mentioned manner, obtained is the reflective mask blank 30 in which the identification symbol 24 (24a), the first reference marks 22 (22a), and the second reference marks 42 are included in the belt-like region 100 having no influence on transfer (see FIG. 6C and FIG. 8).

Next, using the above-mentioned coordinate measuring instrument, the second reference marks 42 and the first reference marks 22a are inspected to detect position coordinates of the first reference marks 22a with respect to the second reference marks 42. Thereafter, using the coordinates of the first reference marks 22a with respect to the second reference marks 42, the defect information (1st defect map) is converted into defect information (1'st defect map) with respect to the second reference marks 42. Thus, it is possible to perform high-accuracy defect management. As a result, it is possible to acquire accurate defect information including defect position information. It is preferable to inspect the first reference marks 22a and the second reference marks 42 by using the coordinate measuring instrument such as LMS-IPRO4 mentioned above. At this time, by detecting the identification symbol 24a using the coordinate measuring instrument, one-by-one management of the reflective mask blank 30 can be performed during relative coordinate management also.

Next, the reflective mask blank 30 having the identification symbol 24a and the first reference marks 22a is subjected to defect inspection using inspection light different from the inspection light by the inspection device which has performed the defect inspection on the multilayer reflective film. Specifically, the reflective mask blank 30, including the first reference marks 22a, is subjected to the defect inspection by the defect inspection device to acquire the defect and the position information detected by the defect inspection and to obtain defect information including the first reference marks 22a. The defect inspection in this case is performed at least over an entire surface of the pattern forming region. Thus, defect information (3rd defect map) with respect to the first reference marks 22a is prepared.

Thereafter, using the coordinates of the first reference marks 22a with respect to the second reference marks 42, the defect information (3rd defect map) is converted into defect information (3'rd defect map) with respect to the second reference marks 42. The identification symbol 24a can be detected during a series of operations of the defect inspection on the reflective mask blank 30. By performing defect inspection on the reflective mask blank 30 to simultaneously detect the defect information and the identification symbol 24a of the reflective mask blank 30, the individual identification of the reflective mask blank 30 and the correlation between the defect information (3rd defect map or 3'rd defect map) and the identification symbol 24a can easily be performed.

Note that the defect inspection on the surface of the reflective mask blank 30 may not be performed. For the defect inspection on the surface of the reflective mask blank 30, partial inspection shortened in inspection time may be performed instead of entire surface inspection.

The reflective mask blank 30 according to the present embodiment includes a configuration in which a hard mask film (also referred to as an etching mask film) is formed on the absorber film 31. The hard mask film has a mask function during patterning of the absorber film 31 and is made of a material different in etching selectivity from a material of an uppermost layer of the absorber film 31. For example, in a case where the absorber film 31 is made of elemental Ta or a material containing Ta, the hard mask film may be formed by using a material such as chromium, a chromium compound, silicon, or a silicon compound. The chromium compound may be a material containing Cr and at least one element selected from N, O, C, and H. The silicon compound may be a material containing Si and at least one element selected from N, O, C, and H, or a material, such as metallic silicon (metal silicide) or a metallic silicon compound (metal silicide compound), which contains a metal in addition to silicon or a silicon compound. The metallic silicon compound may be a material containing a metal, Si, and at least one element selected from N, O, C, and H. In a case where the absorber film 31 is made of a material containing Cr, the material of the hard mask film may be selected from silicon, a silicon compound, a metal silicide, a metal silicide compound, a tantalum compound, or the like, which has etching selectivity with respect to the material containing Cr. The tantalum compound may be a material containing Ta and at least one element selected from N, O, C, and H.

The reflective mask blank 30 according to the present embodiment may have a structure in which the absorber film comprises a stacked film of the uppermost layer and other layers made of materials different in etching selectivity from one another, and the uppermost layer has a function as a hard mask film for the other layers.

As described above, the absorber film 31 in the reflective mask blank 30 according to the present embodiment is not limited to a single-layer film and may comprise a stacked film of the same material or a stacked film of different materials. Furthermore, it is possible to use a stacked film including a hard mask film and the absorber film which is the stacked film or the single-layer film as mentioned above.

The reflective mask blank 30 according to the present embodiment also includes a configuration in which a resist film is formed on the absorber film 31. Such a resist film is used when the absorber film 31 in the reflective mask blank is patterned by photolithography.

In a case where the resist film is formed on the absorber film 31 with or without the hard mask film interposed therebetween, the shapes of the second reference marks 42 and the identification symbol 24a are transferred to the resist film. During electron beam drawing, the identification symbol 24a transferred to the resist film is detected so as to perform individual identification. The second reference marks 42 transferred to the resist film have a contrast in response to electron beam scanning by the electron beam drawing device, and can be detected by the electron beam. At this time, management of relative coordinates is carried out using the first reference marks 22 and the second reference marks 42. Therefore, high-accuracy drawing can be performed even if the shapes of the first reference marks 22 (22a) relatively smaller than the second reference marks 42 are not transferred to the resist film.

In order to further improve the contrast in response to the electron beam scanning and to facilitate detection, the resist film may not be formed on the region including the second reference marks 42 and the identification symbol 24a, or the resist film on the region including the second reference marks 42 may be removed.

The present disclosure also provides a method for manufacturing a reflective mask using the reflective mask blank.

As a method of patterning the absorber film 31, which serves as a transfer pattern, in the reflective mask blank 30, photolithography is most preferable. Specifically, the resist film is formed by applying a resist for electron beam drawing onto the reflective mask blank 30 and baking the resist. The resist film is subjected to drawing and development by using the electron beam drawing device to form, on the resist film, a resist pattern corresponding to the transfer pattern. Thereafter, the absorber film 31 is patterned with the resist pattern used as a mask to form an absorber film pattern 31a. Thus, the reflective mask 40 is manufactured (see FIG. 6D).

In a case where the reflective mask is manufactured using the reflective mask blank having a configuration including the hard mask film, the hard mask film may be finally removed, but may not be removed provided that no influence is given to the function as the reflective mask even if the hard mask film is left.

In the present embodiment, the identification symbol 24 is transferred to the surface of the reflective mask blank 30. Therefore, it is possible to perform one-by-one management of the reflective mask blank 30 in a mask manufacturing process. On the surface of the reflective mask blank 30, the second reference marks 42 are formed to perform alignment in an electron beam drawing step in mask manufacture. Based on the above-mentioned defect information (1'st defect map and/or 3'rd defect map) with reference to the second reference marks 42, the absorber film 31 can be patterned with reference to the second reference marks 42.

Thus, in the present disclosure, high-accuracy defect information including the defect position information in the multilayer reflective film can be acquired while performing one-by-one management of the reflective mask blank, so that the defect management of the reflective mask blank can be performed with high accuracy, as described above. Therefore, in manufacture of the reflective mask, it is possible to perform comparison with preliminarily designed drawing data (mask pattern data) based on the defect information and to correct (amend) the drawing data with high accuracy so as to reduce the influence of the defect. As a result, the defect is reduced in the reflective mask finally manufactured.

Furthermore, a high-quality semiconductor device with less defects can be manufactured by transferring by exposure the transfer pattern to the resist film on a semiconductor substrate using the above-mentioned reflective mask according to the present disclosure.

In the foregoing, the multilayer reflective film coated substrate and the reflective mask blank have been described as one embodiment of the present disclosure. Not being limited thereto, the present disclosure may advantageously be applied to, for example, a photomask blank using ultraviolet light as an exposure light source. In a mask blank having a transparent substrate, such as a glass substrate, and a thin film on the transparent substrate (for example, a light-shielding film made of a chromium-based material such as chromium and a chromium compound, a phase shift film made of a material such as silicon, a silicon compound, or the like), the thin film being for forming a transfer pattern (mask pattern), an identification symbol unique to the mask blank is provided on a surface on the side where the thin film is formed, in a region having no influence on transfer. The mask blank is subjected to defect inspection to simultaneously detect the defect information and the identification symbol of the thin film so that the identification symbol can be correlated with the defect information of the thin film. Thus, by providing the mask blank with the identification symbol unique to the mask blank and detectable by the defect inspection device for the mask blank, the identification symbol can be detected simultaneously with the defect inspection on the mask blank. As a result, the individual identification of the mask blank and the correlation between the defect information of the thin film and the identification symbol can easily be performed so as to perform appropriate one-by-one management of the mask blank.

### EXAMPLES

In the following, embodiments of the present disclosure will be described more in detail with reference to examples.

### Example 1

A SiO₂-TiO₂-based glass substrate (6-inch square substrate having a size of about 152.0 mm×about 152.0 mm and a thickness of about 6.35 mm) was prepared whose substrate surfaces were stepwise polished by cerium oxide abrasive grains or colloidal silica abrasive grains by using a double-sided polishing device and surface-treated with low-concentration fluorosilicic acid. The surface roughness of the obtained glass substrate was 0.25 nm in root mean square roughness (Rq). The surface roughness was measured by an atomic force microscope (AFM), and a measurement region was 1 μm×1μm.

Next, by using an ion beam sputtering apparatus, 40 periods of films were stacked on a main surface of the glass substrate where one period includes a Si film (film thickness: 4.2 nm) and a Mo film (film thickness: 2.8 nm). Finally, another Si film (film thickness: 4 nm) was formed. Furthermore, a protective film (film thickness: 2.5 nm) of Ru was formed thereon to obtain a multilayer reflective film coated substrate.

Next, an identification symbol comprising a QR code (registered trademark) composed of a plurality of dots having a concave cross-sectional shape was formed at a predetermined position on the surface of a multilayer reflective film of the multilayer reflective film coated substrate. Specifically, the identification symbol was formed by laser processing in a belt-like region, having no influence on transfer, between a pattern forming region having a size of 132 mm×132 mm and a defect inspection region having a size of 140 mm×140 mm. The identification symbol can provide unique information to the multilayer reflective film coated substrate, and has a shape and a size which can be detected by a defect inspection device used for defect inspection of the multilayer reflective film coated substrate. Conditions of the laser processing were as follows.
type of laser: semiconductor laser having a wavelength of 405 nm
output of laser: 7 mW (continuous wave)
spot size: 430 nmϕ

The identification symbol had a size falling within a rectangle of 100 μm in length and 100 μm in width, assuming that an ABI device manufactured by Lasertec and having an inspection light source wavelength of 13.5 nm is used as the defect inspection device.

Next, first reference marks having a concave cross-sectional shape were formed by laser processing near four corners in the same belt-like region. The first reference mark had a shape illustrated in FIG. 5A described above, specifically, a circular shape having a diameter of 1.5 μm, and a depth of 40 nm.

After the identification symbol and the first reference marks were formed, cleaning was performed.

In the above-mentioned manner, a multilayer reflective film coated substrate was manufactured in which the identification symbol and the first reference marks were formed on the surface of the multilayer reflective film.

Next, using the ABI device, the identification symbol and the first reference marks on the surface of the multilayer reflective film coated substrate were detected and, simultaneously, defect inspection was performed on a region of 140 mm×140 mm. In the defect inspection, defect position information and defect size information of convex portions and concave portions were acquired to obtain defect information (1st defect map) including the first reference marks. Thus, it was possible to easily correlate the defect information of the multilayer reflective film coated substrate with the identification symbol, so that one-by-one management of the multilayer reflective film coated substrate could appropriately be performed. In a conventional method of performing individual identification by performing collation with a defect map prior to preparation of a reflective mask, there was a problem that the comparison with the defect map could not be performed when the number of defects is small or zero. According to the present disclosure, even when the number of defects is small or zero, it is possible to correlate the defect information of the multilayer reflective film coated substrate with the identification symbol by detecting the identification symbol, so that the one-by-one management of the multilayer reflective film coated substrate can appropriately be performed.

### Example 2

In Example 2, in addition to the defect inspection by the ABI device in Example 1, another defect inspection was performed by an EUV exposure mask substrate/blank defect inspection device “MAGICS M8850”, manufactured by Lasertec, having an inspection light source wavelength of 355 nm.

In the manner similar to Example 1, a multilayer reflective film coated substrate having the identification symbol and the first reference marks on the surface of the multilayer reflective film was prepared.

Next, using the ABI device, the identification symbol and the first reference marks on the surface of the multilayer reflective film coated substrate were detected and, simultaneously, first defect inspection was performed on a region of 140 mm×140 mm. In the first defect inspection, defect position information and defect size information of convex portions and concave portions were acquired to obtain first defect information (1st defect map) including the first reference marks.

Next, using the defect inspection device MAGICS M8650, the identification symbol and the first reference marks on the surface of the multilayer reflective film coated substrate were detected and, simultaneously, second defect inspection was performed on the region of 140 mm×140 mm. In the second defect inspection, defect position information and defect size information of the convex portions and the concave portions were acquired to obtain second defect information (2nd defect map) including the first reference marks. Thus, it was possible to easily correlate the first defect information and the second defect information of the multilayer reflective film coated substrate with the identification symbol, so that one-by-one management of the multilayer reflective film coated substrate could appropriately be performed. Furthermore, by performing defect inspection on the multilayer reflective film coated substrate at different wavelengths, it is possible to perform one-by-one management with more accurate defect information correlated with the identification symbol.

### Example 3

Using a DC magnetron sputtering apparatus, an absorber film comprising a stacked film including a TaBN film (film thickness: 56 nm) and a TaBO film (film thickness: 14 nm) was formed on the protective film of the multilayer reflective film coated substrate obtained in Example 1. A TaB conductive film (film thickness: 70 nm) was formed on a back surface of the multilayer reflective film coated substrate to obtain a reflective mask blank.

Next, second reference marks were formed by photolithography at predetermined four positions on the surface of the reflective mask blank. As the second reference marks, a cross shape shown in FIG. 7A was formed. The second reference marks each had a cross shape with a width of 5 μm and a length of 1 mm, and a depth of about 70 nm.

The reflective mask blank thus obtained was inspected by using a mask/blank defect inspection device “Teron 610” manufactured by KLA-Tencor and having an inspection light source wavelength of 193 nm to detect the identification symbol and the first reference marks on the surface of the reflective mask blank and to perform third defect inspection on a region of 140 mm×140 mm. In the third defect inspection, defect position information and defect size information of convex portions and concave portions were acquired to obtain third defect information (3rd defect map) including the first reference marks. Thus, it was possible to easily correlate the third defect information of the reflective mask blank with the identification symbol, so that one-by-one management of the reflective mask blank could appropriately be performed.

Next, by using a coordinate measuring instrument “LMS-IPRO4” manufactured by KLA-Tencor and adapted to perform coordinate measurement with a laser having a wavelength of 365 nm, the first reference marks and the second reference marks were measured. With reference to relative position coordinates of the first and the second reference marks, position coordinates of the first reference marks with respect to the second reference marks were detected. By managing the relative coordinates of the second and the first reference marks, defects on the multilayer reflective film can be managed with high accuracy with respect to the second reference marks.

Thus, the defect information (1'st defect map) of the multilayer reflective film coated substrate with respect to the second reference marks and the defect information (3'rd defect map) of the reflective mask blank were obtained.

Next, by using the reflective mask blank having the identification symbol, a reflective mask was manufactured.

First, a resist for electron beam writing was applied on the reflective mask blank by spin coating and baked to form a resist film. The identification symbol was also transferred to the resist film. Thereby, one-by-one management of the reflective mask blank with the resist film can be performed.

Thereafter, alignment was performed based on the second reference marks. Then, based on the defect information (1'st defect map and 3'rd defect map) of the reflective mask blank, comparison with mask pattern data preliminarily designed was performed. Mask pattern data were corrected so as not to affect pattern transfer using an exposure apparatus. Alternatively, when judging that the pattern transfer would be affected, the mask pattern data were corrected, for example, by adding correction pattern data to conceal the defects under a pattern. Then, a mask pattern was drawn by an electron beam and developed to form a resist pattern.

Using the resist pattern as a mask, the absorber film was etched to remove the TaBO film by a fluorine-based gas (CF₄ gas) and the TaBN film by a chlorine-based gas (Cl₂ gas) to form an absorber film pattern on the protective film.

Furthermore, the resist pattern left on the absorber film pattern was removed by hot sulfuric acid to obtain a reflective mask.

The reflective mask thus obtained was set in the exposure apparatus and pattern transfer was performed onto a semiconductor substrate with a resist film formed thereon. As a result, excellent pattern transfer was performed without defects in a transfer pattern due to the reflective mask.

### DESCRIPTION OF REFERENCE NUMERALS

10 glass substrate
20 multilayer reflective film coated substrate
21 multilayer reflective film
22 first reference mark
24 identification symbol
30 reflective mask blank
31 absorber film
40 reflective mask
42 second reference mark
42a main mark
42b, 42c, 42d, 42e auxiliary mark
100 belt-like region

1. A method for manufacturing a thin film coated substrate comprising a substrate and a thin film formed on the substrate; the method comprising:
providing the thin film coated substrate which includes an identification symbol, wherein the identification symbol is used to uniquely identify the thin film coated substrate, and is located on the thin film coated substrate on the side where the thin film is formed and in a region having no influence on pattern transfer;
detecting defect information of the thin film and the identification symbol utilizing a defect inspection device that is utilized to perform defect inspection of the thin film coated substrate; and
correlating the identification symbol with the defect information of the thin film.

2. The method for manufacturing a thin film coated substrate according to claim 1, wherein the identification symbol has a size within a rectangle with a length of 10 μm to 500 μm and a width of 10 μm to 500 μm.

3. The method for manufacturing a thin film coated substrate according to claim 1, wherein:
the substrate is a 6-inch square substrate; and
the region having no influence on pattern transfer is a belt-like region between a pattern forming region having a size of 132 mm×132 mm and a region having a size of 148 mm×148 mm.

4. The method for manufacturing a thin film coated substrate according to claim 1, wherein a reference mark is provided in the region having no influence on pattern transfer.

5. The method for manufacturing a thin film coated substrate according to claim 1, wherein the thin film comprises a stacked film comprising two or more layers, the method comprising performing two or more defect inspections after formation of the respective layers of the stacked film, and detecting the identification symbol when each defect inspection is performed.

6. A thin film coated substrate comprising:
a substrate; and
a thin film formed on the substrate, wherein
unique identification symbol on a surface of at least one thin film of the thin film coated substrate and in a region having no influence on pattern transfer, the identification symbol having a size and shape capable of being detected utilizing a defect inspection device that is utilized to perform defect inspection of the thin film.

7. The thin film coated substrate according to claim 6, wherein the identification symbol has a size within a rectangle with a length of 10 μm to 500 μm and a width of 10 μm to 500 μm.

8. The thin film coated substrate according claim 6, wherein:
the substrate is a 6-inch square substrate: and
the region having no influence on pattern transfer is a belt-like region between a pattern forming region having a size of 132 mm×132 mm and a region having a size of 148 mm×148 mm.

9. The thin film coated substrate according to claim 6, wherein a reference mark is provided in the region having no influence on pattern transfer.

10. The method for manufacturing a thin film coated substrate according to claim 1, wherein the thin film comprises a multilayer reflective film formed on the substrate to reflect EUV light, the method further comprising:
detecting defect information of the multilayer reflective film and the identification symbol when defect inspection is performed on the multilayer reflective film coated substrate; and
correlating the identification symbol with the defect information of the multilayer reflective film.

11. (canceled)

12. (canceled)

13. (canceled)

14. (canceled)

15. A multilayer reflective film coated substrate comprising:
a substrate; and
a multilayer reflective film formed on the substrate, wherein
unique identification symbol provided on a surface of the multilayer reflective film coated substrate and in a region having no influence on pattern transfer, the identification symbol having a size and shape capable of being detected utilizing a defect inspection device that is utilized to perform defect inspection of the multilayer reflective film.

16. The multilayer reflective film coated substrate according to claim 15, wherein the multilayer reflective film coated substrate further comprises a protective film on the multilayer reflective film.

17. The multilayer reflective film coated substrate according to claim 15, wherein the identification symbol has a size within a rectangle with a length of 10 μm to 500 μm and a width of 10 μm to 500 μm.

18. The multilayer reflective film coated substrate according to claim 15, wherein:
the substrate is a 6-inch square substrate: and
the region having no influence on pattern transfer is a belt-like region between a pattern forming region having a size of 132 mm×132 mm and a region having a size of 148 mm×148 mm.

19. The multilayer reflective film coated substrate according to claim 15, wherein a reference mark is provided in the region having no influence on pattern transfer.

20. (canceled)

21. (canceled)

22. (canceled)

23. The method for manufacturing a thin film coated substrate according to claim 4, wherein the reference mark and identification symbol are both detected utilizing the defect inspection device that is utilized to perform defect inspection of the thin film coated substrate.

24. The method for manufacturing a thin film coated substrate according to claim 10, wherein a reference mark is provided in the region having no influence on pattern transfer.

25. The method for manufacturing a thin film coated substrate according to claim 24, wherein detecting defect information of the multilayer reflective film comprises utilizing the reference mark during defect inspection and then correlating the defect information with the identification symbol.

26. The thin film coated substrate according to claim 7, wherein the identification symbol has a layout consisting of one of a QR code, a bar code, alphanumeric characters, and a dot mark array.

27. The multilayer reflective film coated substrate according to claim 17, wherein the identification symbol has a layout consisting of one of a QR code, a bar code, alphanumeric characters, and a dot mark array.
